(19) United States
(12) Patent Application Publication
(10) Pub. No.: US 2020/0355645 A1
(43) Pub. Date: Nov. 12, 2020

(54) THIN FILM TRANSISTOR, MANUFACTURING METHOD THEREOF, DISPLAY DEVICE AND METHOD FOR DETECTING AN ION CONCENTRATION

(71) Applicant: BOE TECHNOLOGY GROUP CO., LTD., Beijing (CN)

(72) Inventor: Xiaochen MA, Beijing (CN)

(21) Appl. No.: 16/472,584

(22) PCT Filed: Dec. 27, 2018
(86) PCT No.: PCT/CN2018/124266

§ 371 Date: Jun. 21, 2019

(30) Foreign Application Priority Data
Jan. 31, 2018 (CN) 201810097513.7

(51) Int. Cl. G01N 27/414; H01L 29/49; H01L 29/51; H01L 29/786; H01L 29/66

(52) U.S. Cl. CPC G01N 27/4145; H01L 29/4908; H01L 29/66969; H01L 29/7869; H01L 29/517

(57) ABSTRACT

Embodiments of the present disclosure provide a transistor, a manufacturing method thereof, a display device and a method for detecting an ion concentration. The transistor includes a gate insulating layer including a solid porous electrolyte.

### CROSS REFERENCE TO RELATED APPLICATIONS

The present application claims the benefit of Chinese Patent Application No. 201810097513.7, filed on Jan. 31, 2018, the entire disclosure of which is incorporated herein by reference.

### FIELD

The present disclosure relates to the field of transistor technologies, and particularly to a thin film transistor, a manufacturing method thereof, a display device and a method for detecting an ion concentration.

### BACKGROUND

Thin film transistors have advantages such as high carrier concentration, high mobility, low off-state current, and the like, and are hence widely used in the manufacturing industry.

Generally, a turn-on voltage of a SiO₂ gate thin film transistor is about 15V, and turn-on voltages of gate thin film transistors with high dielectric constant materials Ta₂O₃, HfO₂ and ZrO₂ are about 3V, 5V and 6V, respectively. In order to further decrease the turn-on voltage of a thin film transistor, a thickness of a gate layer may be reduced. However, if the gate layer is too thin, a leakage current of the thin film transistor will be large. Therefore, it is currently impossible to manufacture a thin film transistor having both a low leakage current and a low turn-on voltage.

In addition, using a high dielectric constant material as a gate dielectric is also a method for decreasing an operating voltage of a thin film transistor. However, the high dielectric constant material has a large defect density, so that a bias stress of the thin film transistor is often unstable, which thus affects operational stability of the thin film transistor.

### SUMMARY

An aspect of the present disclosure provides a transistor comprising a gate insulating layer, wherein the gate insulating layer comprises a solid porous electrolyte.

According to some embodiments of the present disclosure, the solid porous electrolyte comprises a solid porous metal oxide electrolyte.

According to some embodiments of the present disclosure, the solid porous metal oxide electrolyte comprises one of a solid porous Al₂O₃ electrolyte and a solid porous Ga₂O₃ electrolyte.

According to some embodiments of the present disclosure, the solid porous Al₂O₃ electrolyte has a density ranging from about 0.06 to 3.5 g/cm³.

According to some embodiments of the present disclosure, the solid porous metal oxide electrolyte has a thickness ranging from about 30 to 5000 nm.

According to some embodiments of the present disclosure, a porous structure in the solid porous metal oxide electrolyte has a pore size between about 0.1 and 10 nm.

According to some embodiments of the present disclosure, the above transistor further comprises a base substrate, a gate on the base substrate, an active layer, and a first terminal and a second terminal on the active layer, wherein the gate insulating layer is located between the gate and the active layer.

According to some embodiments of the present disclosure, the above transistor further comprises a base substrate, a first terminal and a second terminal on the base substrate, an active layer, and a gate on the active layer, wherein the gate insulating layer is located between the gate and the active layer.

According to some embodiments of the present disclosure, the transistor is a thin film transistor.

Another aspect of the present disclosure provides a display device comprising any of the transistors described above.

A further aspect of the present disclosure provides a manufacturing method of a transistor, comprising: forming a solid porous electrolyte on a base substrate by a sputtering process, the solid porous electrolyte serving as a gate insulating layer of the transistor.

According to some embodiments of the present disclosure, a sputtering target of the sputtering process is a metal oxide.

According to some embodiments of the present disclosure, the metal oxide comprises one of Al₂O₃ and Ga₂O₃.

According to some embodiments of the present disclosure, a sputtering target of the sputtering process is a metal. The sputtering process comprises introducing oxygen into a sputtering chamber such that sputtered particles generated by bombarding the sputtering target are oxidized with oxygen to form a solid porous metal oxide electrolyte sputtered onto the base substrate.

According to some embodiments of the present disclosure, the metal comprises one of Al and Ga.

According to some embodiments of the present disclosure, a power density used to bombard the sputtering target in the sputtering process is no greater than about 3 W/cm².

According to some embodiments of the present disclosure, in the sputtering process, an operating pressure within the sputtering chamber is in a negative pressure environment, the negative pressure environment being no less than about 0.001 mbar.

According to some embodiments of the present disclosure, in the sputtering process, a temperature of the base substrate is maintained below about 150 degrees Celsius.

Yet another aspect of the present disclosure provides a method for detecting an ion concentration of a to-be-detected sample solution using any of the transistors described above, comprising: applying a first voltage signal to a gate of the transistor, the transistor outputting a first electrical signal in response to the first voltage signal; maintaining the first voltage signal, bringing the solid porous electrolyte of the transistor into contact with the to-be-detected sample solution, and detecting a second electrical signal outputted by the transistor; and comparing the second electrical signal with the first electrical signal, and obtaining the ion concentration of the to-be-detected sample solution based on the comparison.

According to some embodiments of the present disclosure, the to-be-detected sample solution is selected from a group comprising an acid solution, an alkali solution, a biological sample, and a medical sample.

The above description is only an overview of the technical solutions of the present disclosure. To enable technical measures of the present disclosure to be understood more clearly and implemented in accordance with the contents of the specification, the present disclosure will be described in detail below in conjunction with exemplary embodiments and the accompanying drawings.

### BRIEF DESCRIPTION OF DRAWINGS

Other advantages and benefits will become apparent to those ordinarily skilled in the art through reading detailed description of exemplary embodiments below. The drawings are only for the purpose of illustrating the exemplary embodiments and are not to be construed as limiting the present disclosure. Moreover, the same components are denoted by the same reference numerals throughout the drawings. In the drawings:

FIG. 1 is a schematic structural view of a thin film transistor provided by an embodiment of the present disclosure;

FIG. 2 is a flow chart of a manufacturing method of a thin film transistor provided by an embodiment of the present disclosure;

FIG. 3 is a schematic structural view of a solid porous metal oxide electrolyte of a thin film transistor provided by an embodiment of the present disclosure viewed under a scanning electron microscope SEM;

FIG. 4 is a schematic structural view of a solid porous metal oxide electrolyte of a thin film transistor provided by an embodiment of the present disclosure viewed under a transmission electron microscope TEM;

FIG. 5 is a schematic view illustrating selected area electron diffraction (SAED) of a solid porous metal oxide electrolyte of a thin film transistor provided by an embodiment of the present disclosure;

FIG. 6 is a schematic view illustrating a transfer characteristic curve of a thin film transistor provided by an embodiment of the present disclosure.

### DETAILED DESCRIPTION

To further illustrate the technical measures adopted by the present disclosure for achieving the intended inventive purpose and the effect thereof, implementations, structures, features and effects of the thin film transistor, the manufacturing method thereof, the display device and the method for detecting an ion concentration proposed by the present disclosure are described in detail below with reference to the accompanying drawings and exemplary embodiments. In the description below, different expressions “an embodiment” or “embodiment” do not necessarily refer to the same embodiment. Furthermore, specific features, structures or features in one or more embodiments may be combined in any suitable form.

An embodiment of the present disclosure provides a transistor (e.g. thin film transistor) in which a gate insulating layer is made of a solid porous electrolyte such as a solid porous metal oxide electrolyte. Due to the porous structure therein, the solid porous electrolyte will adsorb moisture in a surrounding environment. After the solid porous electrolyte adsorbs moisture, a large amount of movable charged ions such as hydrogen ions H+ and hydroxide ions OH− will be generated inside the solid porous electrolyte. When a voltage is applied to a gate of the transistor, the hydrogen ions H− in the solid porous electrolyte will move and accumulate towards an interface between the active layer and the gate insulating layer, while the hydroxide ions OH− hardly move towards the interface because they are bulky. The accumulated hydrogen ions H+ at the interface between the active layer and the gate insulating layer will attract electrons in the active layer (in the case of an N-type transistor), and repel holes in the active layer (in the case of a P-type transistor), so that negative ions in the active layer also generally move and accumulate towards the interface between the active layer and the gate insulating layer, thereby forming a capacitor having two charged layers with the accumulated hydrogen ions H+. Since a turn-on voltage of the transistor is inversely proportional to the total capacitance of the gate insulating layer, the presence of the above capacitor will cause a decrease in the turn-on voltage of the transistor. That is, this transistor can be turned on with a lower voltage (e.g. 1-2V) applied to its gate. Compared to an existing transistor, the transistor provided by an embodiment of the present disclosure can be turned on by a low voltage at the gate, and produces a lower leakage current.

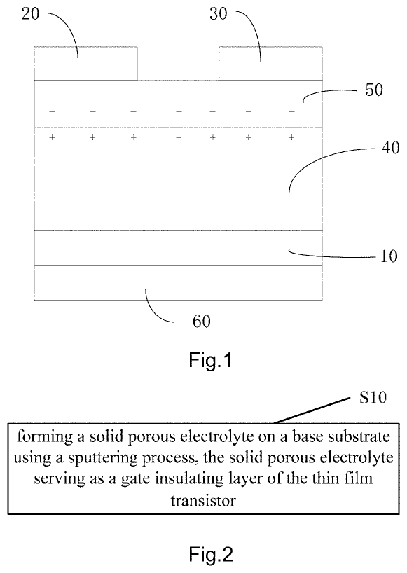

FIG. 1 is a schematic view of a thin film transistor provided by an embodiment of the present disclosure. As shown in FIG. 1, the thin film transistor comprises a gate 10, a source 20, a drain 30, a gate insulating layer 40, and an active layer 50. The gate insulating layer 40 comprises a solid porous electrolyte. For example, the gate insulating layer 40 may comprise a solid porous metal oxide electrolyte. Alternatively, the gate insulating layer 40 may also comprise other solid porous electrolytes. In this transistor, the gate insulating layer is made of a solid porous electrolyte such as a solid porous metal oxide electrolyte. Due to the porous structure therein, the solid porous electrolyte will adsorb moisture in a surrounding environment. After the solid porous electrolyte adsorbs moisture, a large amount of movable charged ions such as hydrogen ions H+ and hydroxide ions OH− will be generated inside the solid porous electrolyte. When a voltage is applied to the gate of the transistor, the hydrogen ions H− in the solid porous electrolyte will move and accumulate towards an interface between the active layer and the gate insulating layer, while the hydroxide ions OH− hardly move towards the interface because they are bulky. The accumulated hydrogen ions H+ at the interface between the active layer and the gate insulating layer will attract electrons in the active layer (in the case of an N-type transistor), and repel holes in the active layer (in the case of a P-type transistor), so that negative ions in the active layer also generally move and accumulate towards the interface between the active layer and the gate insulating layer, thereby forming a capacitor having two charged layers with the accumulated hydrogen ions H+. Since a turn-on voltage of the transistor is inversely proportional to the total capacitance of the gate insulating layer, the presence of the above capacitor will cause a decrease in the turn-on voltage of the transistor. That is, the transistor can be turned on with a lower voltage (e.g. 1-2 V) applied to its gate. Compared to an existing transistor, the transistor provided by an embodiment of the present disclosure can be turned on by a low voltage at the gate, and produces a lower leakage current.

In the above embodiment, the source 20 and the drain 30 are located on one side of the gate insulating layer 40, and the gate 10 is located on the other side of the gate insulating layer 40. Specifically, as shown in FIG. 1, the gate 10 is disposed on a base substrate 60, and the gate insulating layer 40 is disposed on the gate 10. A semiconductor active layer 50 is formed on the gate insulating layer 40, and the source 20 and the drain 30 are formed on the semiconductor active layer 50.

It is to be noted that although FIG. 1 illustrates the principle of the present disclosure by taking a bottom gate type thin film transistor as an example, the present disclosure is not so limited. In an alternative embodiment, the thin film transistor has a top gate structure, in which the source and the drain are disposed on the base substrate, the gate insulating layer is superposed on the source and the drain, and the gate is disposed on the gate insulating layer.

Pore size of the porous structure in the solid porous metal oxide electrolyte may be between 0.1 and 10 nm, such as 0.3 nm, 2 nm, 5 nm, 8 nm and the like. Shape of the pore is usually an irregular hole, and the pore diameter thereof can be understood as the maximum outer diameter size. With this pore diameter, the physical structure of the solid porous metal oxide electrolyte is stable, and moisture can easily get thereinto to thereby generate ions.

Taking a solid porous metal oxide electrolyte including a solid porous Al₂O₃ electrolyte as an example, the density of the solid porous Al₂O₃ electrolyte can be controlled to range from 0.06 to 3.5 g/cm³. The solid porous metal oxide electrolyte may also employ a substance other than the solid porous Al₂O₃ electrolyte, for example, a solid porous Ga₂O₃ electrolyte.

The thickness of the solid porous metal oxide electrolyte itself has a small impact on the formed electrical double layer capacitor. In an exemplary embodiment, the thickness ranges from 30 to 5000 nm.

Advantageously, when a thickness uniformity of the solid porous metal oxide electrolyte is greater than 80%, the output of the thin film transistor is relatively stable. As used herein, the thickness uniformity of the solid porous metal oxide electrolyte means a ratio of the minimum thickness of the solid porous metal oxide electrolyte to the maximum thickness thereof.

An embodiment of the present disclosure further provides a display device using any of the thin film transistors described above. In such a display device, the gate insulating layer of the transistor is made of a solid porous electrolyte such as a solid porous metal oxide electrolyte. Due to the porous structure therein, the solid porous electrolyte will adsorb moisture in a surrounding environment. After the solid porous electrolyte adsorbs moisture, a large amount of movable charged ions such as hydrogen ions H+ and hydroxide ions OH− will be generated inside the solid porous electrolyte. In case a voltage is applied to the gate of the transistor, the hydrogen ions H− in the solid porous electrolyte will move and accumulate towards an interface between the active layer and the gate insulating layer, while the hydroxide ions OH− hardly move to the interface because they are bulky. The accumulated hydrogen ions at the interface between the active layer and the gate insulating layer will attract electrons in the active layer (in the case of an N-type transistor), and repel holes in the active layer (in the case of a P-type transistor), such that negative ions in the active layer also generally move and accumulate towards the interface between the active layer and the gate insulating layer, thereby forming a capacitor having two charged layers with the accumulated hydrogen ions H+. Since the turn-on voltage of the transistor is inversely proportional to the total capacitance of the gate insulating layer, the presence of the above capacitor will cause a decrease in the turn-on voltage of the transistor. That is, the transistor can be turned on with a lower voltage (e.g. 1-2 V) applied to its gate. Compared to an existing transistor, the transistor provided by an embodiment of the present application can be turned on by a low voltage at the gate and produce a lower leakage current. Therefore, the display device provided by an embodiment of the present disclosure has lower power consumption.

The display device can be any product or component having a display function such as a display panel, a mobile phone, a tablet computer, a television, a display, a notebook computer, a digital photo frame, a navigator, and the like.

In the above display device, since the thin film transistor therein can be turned on under the control of a low gate voltage (1-2 V), the thin film transistor can be controlled by the display device at a low gate voltage, thereby reducing the power consumption of the display device.

An embodiment of the present disclosure further provides a manufacturing method of a thin film transistor, wherein a solid porous electrolyte is prepared by a sputtering process, and therefore the prepared solid porous electrolyte is uniform in thickness, so that the operation of the thin film transistor is stabilized.

As shown in FIG. 2, the manufacturing method of a thin film transistor proposed by an embodiment of the present disclosure comprises, in step S10, forming a solid porous electrolyte on a base substrate by a sputtering process, the solid porous electrolyte serving as a gate insulating layer of the thin film transistor.

In the technical solution provided by an embodiment of the present disclosure, the solid porous electrolyte prepared by a sputtering process has a uniform thickness, and is thus suitable for serving as a gate insulating layer of the thin film transistor. In the transistor manufactured by the manufacturing method, the gate insulating layer is made of a solid porous electrolyte such as a solid porous metal oxide electrolyte. Due to the porous structure therein, the solid porous electrolyte will adsorb moisture in the surrounding environment. After the solid porous electrolyte adsorbs moisture, a large amount of movable charged ions such as hydrogen ions H+ and hydroxide ions OH− will be generated inside the solid porous electrolyte. In case a voltage is applied to the gate of the transistor, the hydrogen ions H− in the solid porous electrolyte will move and accumulate towards an interface between the active layer and the gate insulating layer, while the hydroxide ions OH− hardly move to the interface because they are bulky. The accumulated hydrogen ions H+ at the interface between the active layer and the gate insulating layer will attract electrons in the active layer (in the case of an N-type transistor), and repel holes in the active layer (in the case of a P-type transistor), such that negative ions in the active layer also generally move and accumulate towards the interface between the active layer and the gate insulating layer, thereby forming a capacitor having two charged layers with the accumulated hydrogen ions H+. Since the turn-on voltage of the transistor is inversely proportional to the total capacitance of the gate insulating layer, the presence of the above capacitor will cause a decrease in the turn-on voltage of the transistor. That is, the transistor can be turned on with a lower voltage (e.g. 1-2 V) applied to its gate. Compared to an existing transistor, the transistor provided by an embodiment of the present disclosure can be turned on by a low voltage at the gate, and produce a lower leakage current.

The solid porous electrolyte prepared by an embodiment of the present disclosure has a porous structure, so that when it functions as a gate insulating layer, electric double layers can be formed inside the electrolyte by adsorbing moisture, thereby generating a large capacitance to further decrease the gate turn-on voltage of the thin film transistor. Taking a thin film transistor having a 200 nm-thick gate insulating layer as an example, the turn-on voltage of a common SiO₂ gate thin film transistor is about 15 V, the turn-on voltages of thin film transistors whose gate insulating layers are made of high dielectric constant materials Ta₂O₃, HfO₂ and ZrO₂ are 3V, 5V and 6V respectively, while the turn-on voltage of a thin film transistor based on the electrolyte gate insulating layer is only about 1-2 V. Compared to the thin film transistor with a common SiO₂ gate insulating layer, the gate turn-on voltage of the thin film transistor provided by an embodiment of the present disclosure is nearly 10 times lower.

In an exemplary embodiment, the above manufacturing method further comprises, prior to step S10:
cleaning the base substrate; and
forming a bottom gate pattern on the base substrate.

In such an embodiment, the above step S10 may further comprise forming a solid porous electrolyte having a thickness greater than about 30 nm on the bottom gate pattern on the base substrate using a sputtering process, the solid porous electrolyte serving as a gate insulating layer of the thin film transistor.

In an exemplary embodiment, the above manufacturing method further comprises, after step S10:
depositing or transferring a semiconductor active layer on the gate insulating layer; and
depositing source and drain patterns on the semiconductor active layer.

Specifically, the sputtering process can be performed in a sputtering chamber. Firstly, an ionized gas (such as argon or the like) is introduced into the sputtering chamber. The environment in which a sputtering target is sputtered requires a negative pressure environment, which can be achieved by controlling the operating pressure inside the sputtering chamber. Upon implementation, the negative pressure environment inside the sputtering chamber should be greater than or equal to 0.001 mbar, such as 0.1 mbar, 1 mbar, 10 mbar, and the like.

In a typical sputtering process, the negative pressure value is small, typically less than 0.001 mbar. This negative pressure environment is not suitable for producing a solid porous structure by sputtering. By setting the negative pressure environment inside the sputtering chamber to be greater than or equal to 0.001 mbar, a solid porous electrolyte suitable for functioning as a gate insulating layer of the thin film transistor can be prepared. Further, by setting the magnitudes of different negative pressure environments, the pore size of the prepared solid porous electrolyte can be adjusted as needed.

In the sputtering process, the yield of the solid porous electrolyte can be increased by lowering the temperature of the base substrate, for example, controlling the temperature of the base substrate to be less than 150 degrees Celsius, and further controlling it, for example, to be less than 100 degrees Celsius. In an exemplary embodiment, the base substrate may be placed on a support holder having thermal conductivity, and the support holder may be cooled by a heat dissipation system to thereby lower the temperature of the base substrate on the support holder.

Different sputtering powers can be used for sputtering targets of different materials. In an exemplary embodiment, a low sputtering power may be employed to obtain a solid porous electrolyte. For example, the power density employed to bombard the sputtering target may be less than or equal to about 3 W/cm².

In the above sputtering process, the sputtering apparatus may be a direct current sputtering instrument, a radio frequency sputtering instrument, an intermediate frequency sputtering instrument, or the like. In an exemplary embodiment, the solid porous electrolyte formed may be a solid porous metal oxide electrolyte.

In the above sputtering process, if a sputtering apparatus which can directly sputter an insulating material is used, a metal oxide target may be directly used for sputtering, which may include Al₂O₃ or Ga₂O₃.

In the above sputtering process, if a sputtering apparatus only capable of sputtering a target with good electrical conductivity is used, a target of a metal (such as a metal element or an alloy) corresponding to a metal oxide may be used in such a sputtering apparatus, and oxygen is introduced during the sputtering process for reactive sputtering. The sputtering target used in the sputtering process is a metal, and may include, for example, Al or Ga. In sputtering, oxygen is introduced into a sputtering chamber containing the sputtering target, so that sputtered particles generated by bombarding the sputtering target are oxidized with oxygen to form a solid porous metal oxide electrolyte sputtered onto the base substrate. During the introduction of oxygen, the negative pressure environment inside the sputtering chamber can be controlled to be constant within a certain range. By adjusting the amount of introduced oxygen, the reaction rate and amount of oxidation of the metal can be regulated. Specifically, by increasing the amount of introduced oxygen supplied, more metals can be oxidized.

The solid porous metal oxide electrolyte prepared by the above sputtering method is an amorphous loose, porous structure. Taking a solid porous Al₂O₃ electrolyte as an example, its loose, porous structure has a lower density than ordinary solid Al₂O₃. Moreover, properties of the electrolyte (i.e., solid porous metal oxide electrolyte) vary with sputtering conditions, and the density thereof ranges from about 0.06 to 3.5 g/cm³.

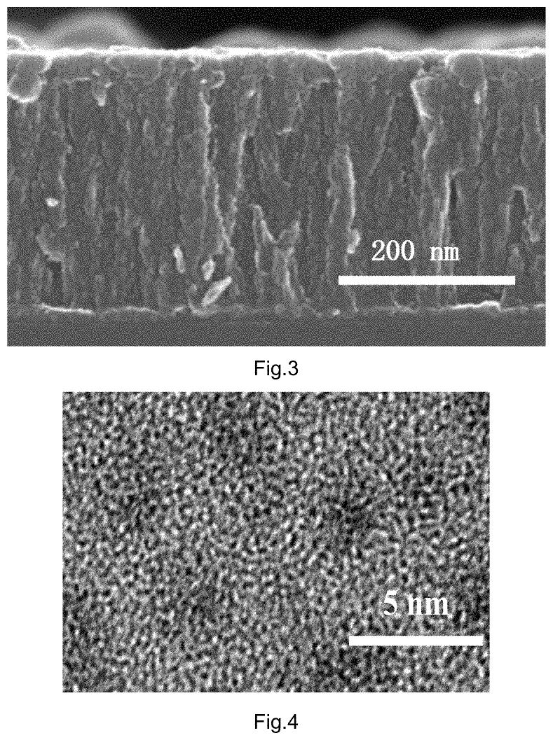

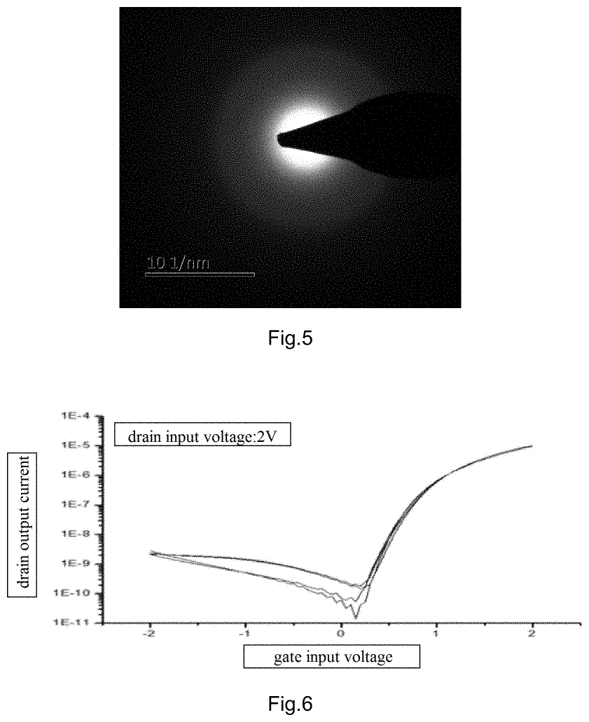

As shown in FIG. 3, FIG. 4 and FIG. 5, FIG. 3 is a schematic structural view of a solid porous metal oxide electrolyte of a thin film transistor provided by an embodiment of the present disclosure viewed under a scanning electronic microscope (SEM) with a scale of 200 nm. A loose mesh structure can be observed from the figure, so that it can be determined that a porous structure is present inside the electrolyte. FIG. 4 is a schematic structural view of a solid porous metal oxide electrolyte of a thin film transistor provided by an embodiment of the present disclosure viewed under a transmission electron microscope (TEM) with a scale of 5 nm. FIG. 5 is a schematic view illustrating selected area electron diffraction of a solid porous metal oxide electrolyte of a thin film transistor provided by an embodiment of the present disclosure. It can be determined from FIG. 4 and FIG. 5 that the electrolyte is amorphous. Due to the porous structure of the solid porous electrolyte, the solid porous electrolyte will adsorb moisture in the surrounding environment. After the solid porous electrolyte adsorbs moisture, a large amount of movable charged ions such as hydrogen ions H+ and hydroxide ions OH− will be generated inside the solid porous electrolyte. In case a voltage is applied to the gate of the transistor, the hydrogen ions H− in the solid porous electrolyte will move and accumulate towards an interface between the active layer and the gate insulating layer, while the hydroxide ions OH− hardly move to the interface because they are bulky. The accumulated hydrogen ions H+ at the interface between the active layer and the gate insulating layer will attract electrons in the active layer (in the case of an N-type transistor), and repel holes in the active layer (in the case of a P-type transistor), such that negative ions in the active layer also generally move and accumulate towards the interface between the active layer and the gate insulating layer, thereby forming a capacitor having two charged layers with the accumulated hydrogen ions H+. Since the turn-on voltage of the transistor is inversely proportional to the total capacitance of the gate insulating layer, the presence of the above capacitor will cause a decrease in the turn-on voltage of the transistor. Taking a 100 nm-thick solid porous metal oxide electrolyte as an example, the electrolyte can generate a capacitance density much higher than the capacitance density 60 nF/cm² of ordinary Al₂O₃. Unlike ordinary Al₂O₃, the capacitance generated by a solid porous metal oxide electrolyte of the same thickness varies with sputtering deposition conditions and the number of ions contained. Based on the response of movable ions, the capacitance generated by the electrolyte will decrease as the frequency increases. In a low frequency range (10-200 Hz), the capacitance per unit area ranges from about 0.01 to 5.0 uF/cm². Since the capacitance is mainly generated by the electric double layers formed by ions, the magnitude of the generated capacitance and the thickness of the electrolyte do not change proportionally. That is, the thickness of the electrolyte has a small impact on the magnitude of the generated capacitance.

FIG. 6 illustrates a transfer characteristic curve of a thin film transistor manufactured by the method described above. As shown in FIG. 6, when a gate input voltage of the thin film transistor is less than 1 V and greater than 0, an output current of the thin film transistor rapidly increases as the gate voltage increases. When the gate input voltage of the thin film transistor is about 2 V, the drain output current of the thin film transistor tends to be stable, and the thin film transistor is turned on. As can be seen from FIG. 6, the gate turn-on voltage of the thin film transistor is relatively low.

On the other hand, in the thin film transistor provided by the above embodiment, the solid porous electrolyte serving as the gate insulating layer will generate a large amount of movable charged ions in a moisture environment, and generate an electric double layer capacitor and a conduction channel after power-on. Therefore, in case the ion concentration in the solid porous electrolyte changes, the turn-on voltage of the thin film transistor will change accordingly. Based on this principle, the thin film transistor according to the above embodiment can be used to detect the ion concentration of a sample solution. Specifically, the solid porous electrolyte layer of the thin film transistor is brought into contact with a to-be-detected sample solution to change the concentration of charged ions inside the thin film transistor, thereby changing the capacitance of the electric double layers. By detecting changes in the turn-on voltage of the thin film transistor and/or the magnitude of the generated drain output current, the ion concentration of the to-be-detected sample solution can be calculated accordingly.

Correspondingly, the method for detecting an ion concentration of a sample solution using the thin film transistor in the above embodiment as proposed by an embodiment of the present disclosure comprises:
applying a first voltage signal to the gate of the thin film transistor, and the thin film transistor outputting a first electrical signal in response to receiving the first voltage signal;
maintaining the first voltage signal, bringing the solid porous electrolyte of the thin film transistor into contact with a to-be-detected sample solution, and detecting a second electrical signal outputted by the thin film transistor;
comparing the second electrical signal with the first electrical signal, and acquiring the ion concentration of the to-be-detected sample solution based on a comparison result.

In the above embodiment, if the to-be-detected sample solution has charged ions, when the solid porous electrolyte is in contact with the to-be-detected sample solution, the number and capacitance of charged ions formed inside the thin film transistor may change, correspondingly causing a change in the output of the thin film transistor. By detecting the change in the output of the thin film transistor, the ion concentration of the to-be-detected sample solution can be calculated.

Specifically, for example, the ion concentration of the to-be-detected sample solution may be determined based on a difference between the second electrical signal and the first electrical signal. If the second electrical signal and the first electrical signal are equal, it is determined that the to-be-detected sample solution does not contain charged ions. If the difference between the second electrical signal and the first electrical signal is not zero, it is determined that the to-be-detected sample solution contains charged ions. The specific ion concentration can be comprehensively calculated according to the parameters such as the characteristics of the thin film transistor, the power supply circuit of the thin film transistor, the chemical properties of the to-be-detected sample solution, and the like. The first electrical signal and the second electrical signal may specifically be a current signal or a voltage signal. Taking the to-be-detected sample solution being an acid solution as an example, since the acid solution contains a large amount of hydrogen ions, after the acid solution is in contact with the solid porous electrolyte layer of the thin film transistor, cations in the solid porous electrolyte will be increased, which induces more carriers in the semiconductor to form a larger electric double layer capacitor, so that an electric signal outputted by the thin film transistor is increased. The ion concentration of the to-be-detected sample solution can be determined by comparing the electrical signals outputted by the thin film transistor before and after the solid porous electrolyte is in contact with the to-be-detected sample solution.

In a specific application, the to-be-detected sample solution is not limited to an acid solution. Other solutions such as an alkali solution, a biological sample, a medical sample or the like may also be applied.

Since the thin film transistor of the above embodiment has a low gate turn-on voltage, the thin film transistor may be used for measuring a weak electrical signal and is widely used.

In the above embodiments, various embodiments are described in different ways, and portions not described in detail in a certain embodiment may be referred to relevant description in other embodiments.

It will be appreciated that related features in the above devices may provide reference for each other. In addition, “first”, “second”, and the like in the above embodiments are used to distinguish the embodiments, and do not represent advantages and disadvantages of the embodiments.

In the specification provided herein, numerous specific details are set forth. However, it can be understood that the embodiments of the present disclosure may be practiced without these specific details. In some instances, well-known structures and techniques have not been shown in detail so as not to obscure the understanding of the specification.

Similarly, it can be understood that, in order to simplify the present disclosure and help to understand one or more of the disclosed aspects, in the above description of exemplary embodiments of the present disclosure, various features of the present disclosure are sometimes grouped together into a single embodiment, figure, or description thereof. However, a disclosed device should not be construed as reflecting the intention that the claimed invention requires more features than those explicitly recited in each of the claims. More accurately, as reflected in the following claims, disclosed aspects lie in all features fewer than the individual embodiments disclosed previously. Therefore, the claims following specific embodiments are hereby explicitly incorporated into the specific embodiments, and each of the claims per se serves as a separate embodiment of the present disclosure.

Those skilled in the art will appreciate that components in a device in an embodiment can be adaptively changed and placed in one or more devices different from the embodiment. Components in embodiments can be combined into one component and, in addition, they can be divided into a plurality of sub-components. In addition to mutual exclusion of at least some of such features, all of the features disclosed in the specification (including the accompanying claims, the abstract and the drawings), and all components of any device so disclosed may be combined in any combination. Each feature disclosed in this specification (including the accompanying claims, the abstract and the drawings) may be replaced by alternative features that provide the same, equivalent or similar purpose, unless specified otherwise.

In addition, those skilled in the art will appreciate that, although some embodiments described herein include certain features that are included in other embodiments and are not other features, combinations of features of different embodiments are intended to be within the scope of the present disclosure and form different embodiments. For example, in the following claims, any one of the claimed embodiments can be used in any combination. Various component embodiments of the present disclosure may be implemented in hardware or in a combination thereof.

It is to be noted that the above-described embodiments are illustrative of the present disclosure and are not intended to limit the scope of the present disclosure, and those skilled in the art can devise alternative embodiments without departing from the scope of the appended claims. In the claims, any reference sign placed inside parentheses shall not be construed as a limitation. The word “comprising” does not exclude the presence of a component or element that is not listed in the claims. The word “a” or “an” preceding a component or element does not exclude the presence of a plurality of such components or elements. The present disclosure can be implemented by means of a device comprising several distinct components. In the claims where several components are enumerated, several of these components may be embodied by the same component item. The use of words such as first, second, third and the like does not indicate any order. These words can be interpreted as names. The term “about” may mean that a deviation between the actual value and the standard value is within a predetermined range, which may be 10%, or less than 10%, such as 5%, 3%, 1%, or the like.

What have been stated above are only preferred embodiments of the present disclosure, which are not intended to limit the present disclosure in any way. Any simple amendments, equivalent variations and modifications made to the above embodiments in accordance with the technical spirit of the present disclosure still fall within the scope of the technical solutions of the present disclosure.

1. A transistor comprising:
a gate insulating layer,
wherein the gate insulating layer comprises a solid porous electrolyte.

2. The transistor according to claim 1, wherein the solid porous electrolyte comprises a solid porous metal oxide electrolyte.

3. The transistor according to claim 2, wherein the solid porous metal oxide electrolyte comprises one of a solid porous Al₂O₃ electrolyte or a solid porous Ga₂O₃ electrolyte.

4. The transistor according to claim 3, wherein the solid porous Al₂O₃ electrolyte has a density ranging from about 0.06 g/cm³ to 3.5 g/cm³.

5. The transistor according to claim 2, wherein the solid porous metal oxide electrolyte has a thickness ranging from about 30 nm to 5000 nm.

6. The transistor according to claim 2, wherein a porous structure in the solid porous metal oxide electrolyte has a pore size between about 0.1 nm and 10 nm.

7. The transistor according claim 1, further comprising:
a base substrate;
a gate on the base substrate;
an active layer; and
a first terminal and a second terminal on the active layer,
wherein the gate insulating layer is between the gate and the active layer.

8. The transistor according to claim 1, further comprising:
a base substrate
a first terminal and a second terminal on the base substrate;
an active layer; and
a gate on the active layer,
wherein the gate insulating layer is located between the gate and the active layer.

9. The transistor according to claim 1, wherein the transistor comprises a thin film transistor.

10. A display device comprising the transistor of claim 1.

11. A method of manufacturing a transistor, comprising:
forming a solid porous electrolyte on a base substrate by a sputtering process,
wherein the solid porous electrolyte serves as a gate insulating layer of the transistor.

12. The method of manufacturing according to claim 11, wherein a sputtering target of the sputtering process comprises a metal oxide.

13. The method of manufacturing according to claim 12, wherein the metal oxide comprises one of Al₂O₃ or Ga₂O₃.

14. The method of manufacturing according to claim 11,
wherein a sputtering target of the sputtering process comprises a metal,
wherein the sputtering process comprises introducing oxygen into a sputtering chamber such that sputtered particles generated by bombarding the sputtering target are oxidized with oxygen to form a solid porous metal oxide electrolyte sputtered onto the base substrate.

15. The manufacturing method of manufacturing according to claim 14, wherein the metal comprises one of Al or Ga.

16. The method of manufacturing according to claim 11, wherein a power density used to bombard a sputtering target in the sputtering process is less than or equal to about 3 W/cm².

17. The method of manufacturing according to claim 11,
wherein in the sputtering process, an operating pressure within a sputtering chamber is in a negative pressure environment,
wherein the negative pressure environment is greater than or equal to about 0.001 mbar.

18. The method of manufacturing according to claim 11, wherein in the sputtering process, a temperature of the base substrate is maintained below about 150 degrees Celsius.

19. A method for detecting an ion concentration of a to-be-detected sample solution using a transistor comprising a gate insulating layer that comprises a solid porous electrolyte, the method comprising:
applying a first voltage signal to a gate of the transistor, the transistor outputting a first electrical signal in response to the first voltage signal;
maintaining the first voltage signal, bringing the solid porous electrolyte of the transistor into contact with the to-be-detected sample solution, and detecting a second electrical signal outputted by the transistor;
comparing the second electrical signal with the first electrical signal; and
obtaining the ion concentration of the to-be-detected sample solution based on the comparing the second electrical signal with the first electrical signal.

20. The method according to claim 19, wherein the to-be-detected sample solution is selected from a group comprising an acid solution, an alkali solution, a biological sample, and a medical sample.
